(19) United States
(12) Patent Application Publication
(10) Pub. No.: US 2010/0081287 A1
(43) Pub. Date: Apr. 1, 2010

(54) DRY ETCHING METHOD

(75) Inventors: Masanobu HONDA, Nirasaki City (JP); Shoichiro Matsuyama, Nirasaki City (JP); Masahiro Ito, Nirasaki City (JP); Hironobu Ichikawa, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/568,374

(22) Filed: Sep. 28, 2009

(30) Foreign Application Priority Data
Sep. 29, 2008 (JP) 2008-250197

(51) Int. Cl. H01L 21/3065

(52) U.S. Cl. 438/719; 257/E21.218

(57) ABSTRACT

A dry etching method includes: mounting a silicon substrate in a processing chamber; generating a plasma by discharging an etching gas in the processing chamber; and etching the silicon substrate by the plasma. The etching gas is a gaseous mixture including a Cl₂ gas and one of an O₂ gas, a rare gas, a HBr gas, a CF₄ gas, and a SF₆ gas.

### CROSS-REFERENCE TO RELATED APPLICATIONS

This application claims priority to Japanese Patent Application No. 2008-250197 filed on Sep. 29, 2008, the entire contents of which are incorporated herein by reference.

### FIELD OF THE INVENTION

The present invention relates to a dry etching method of etching a silicon substrate by using a plasma.

### BACKGROUND OF THE INVENTION

When manufacturing semiconductor devices, the processes of forming a thin film on a silicon substrate and lithographing and patterning the thin film by dry (plasma) etching are repeatedly carried out, and the silicon substrate itself is often dry-etched at the initial stage of the manufacturing processes.

Dry etching of the silicon substrate is mainly carried out for trench formation in silicon, e.g., groove-shaped trenches for device isolation and hole-shaped trenches for capacitor formation. In etching silicon trenches, it is important to control the depth to width ratio (i.e. aspect ratio) and a vertical cross sectional shape of the trench; and especially it is an important issue to prevent bowing etching, which is a barrel-shaped hollow portion of an inner wall of the trench, taper etching, in which a groove gets narrower from top to bottom, and undercut etching below a mask (side etching) and the like. Further, to improve the dimensional accuracy in etching pattern, it is important that a ratio of etching rate of the silicon substrate to that of the etching mask, i.e., mask or etching selectivity or simply selectivity, is sufficiently high (see, e.g., the Japanese Patent Laid-open Application No. 2003-218093).

With ever-increasing demands for high-integration and high-performance of the semiconductor devices manufactured on the silicon substrate, semiconductor elements constituting the devices are made smaller by a scaling rule of about 0.7-times. Therefore, 65 nm and 45 nm design rule (i.e. design standard), which are currently applied to the state-of-the-art semiconductor products, are expected to become about 32 nm in the next-generation products and about 22 nm in the next-next generation products.

If the device design standard approaches to 22 nm in the next-next generation products, a metal insulator semiconductor field effect transistor (MISFET), which is a basic semiconductor device for the large scale integration (LSI) circuits, is highly likely to be changed from a two-dimensional structure (planar structure), in which its channel, source and drain regions are two-dimensionally formed on a main surface of a silicon substrate, to a three-dimensional structure (stereoscopic structure), in which such regions are three-dimensionally formed on the main surface of the silicon substrate.

In the three-dimensional structure, the channel region is formed on a sidewall of a fin or a pillar, which may protrude and extend above the main surface of the silicon substrate, and the source and drain regions are formed at opposite sides of the channel region in the channel length direction. Here, a three-dimensional element body such as the fin or the pillar may be obtained by etching the main surface of the silicon substrate down to a depth of 100 nm or more.

Unlike in the case of a conventional trench etching, the etched sidewall produced by the etching process of such a three-dimensional element is employed as the channel region of the MISFET. Accordingly, if the crystal lattice on the sidewall is damaged due to ion impact, the performance of the MISFET may be significantly deteriorated. In view of the above, it is required that, in the etching process, ions are incident on the substrate with high vertical directivity and a halogen based single gas having a high etching selectivity against SiN and SiO₂ for an etching mask, especially, Cl₂ gas, is often employed.

However, if the single gas of Cl₂ is employed as the etching gas, a fine groove (a microtrench) is easily formed in a lower end portion of the etched sidewall (a bottom edge of an element body). Especially, in the etching process of the silicon substrate, there is no etching stop layer therein and thus the silicon etching is carried out without the etching stop layer. Accordingly, it is highly likely that the microtrench is formed. Further, even though the etching is carried out in the plasma etching apparatus of any plasma generation types, such as capacitively coupled plasma, microwave plasma, inductively coupled plasma, the microtrench is easily formed.

However, if the microtrench is formed at a bottom edge of the three-dimensional element body, especially, a pillar-shaped element body, such microtrench tends to hinder the formation of an impurity region (the source or the drain region) and thus it is difficult to obtain a normal three-dimensional metal insulator semiconductor field effect transistor (MISFET). Accordingly, in the etching of silicon without the etching stop layer, it is required to prevent the microtrench from being formed and etch the bottom portion in a flat or a substantially round shape.

### SUMMARY OF THE INVENTION

In view of the above, the present invention provides a dry etching method that prevents the formation of microtrench and enhances the vertical processability and the mask selectivity in an etching process of a silicon substrate, especially in an etching process for forming a three-dimensional structure on a silicon substrate.

In accordance with an aspect of the present invention, there is provided a dry etching method including: mounting a silicon substrate in a processing chamber; generating a plasma by discharging an etching gas in the processing chamber; and etching the silicon substrate by the plasma. The etching gas is a gaseous mixture including a Cl₂ gas and one of an O₂ gas, a rare gas, a HBr gas, a CF₄ gas, and a SF₆ gas.

### BRIEF DESCRIPTION OF THE DRAWINGS

The objects and features of the present invention will become apparent from the following description of embodiments, given in conjunction with the accompanying drawings, in which:

FIG. 1 is a vertical cross sectional view showing the structure of a capacitively coupled plasma etching apparatus for executing a dry etching method in accordance with the present invention;

FIG. 2A is a block diagram showing one example of a processing gas supply unit;

FIG. 2B is a block diagram showing another example of a processing gas supply unit;

FIG. 2C is a block diagram showing still another example of a processing gas supply unit;

FIG. 3A is a vertical cross sectional view showing one process of an etching of forming a cylindrical pillar-shaped element body by using the dry etching method in accordance with the present invention;

FIG. 3B is a vertical cross sectional view showing a basic shape of the cylindrical pillar-shaped element body produced by the dry etching method in accordance with the present invention;

FIG. 4 is a table where parameters used in test examples A1 and A2 and a comparative example a1, respectively, obtained etching characteristics and SEM pictures are illustrated for the dry etching in accordance with a first experiment;

FIG. 5 is a table where parameters used in test examples B1 to B3, respectively, obtained etching characteristics and SEM pictures are illustrated for the dry etching in accordance with a second experiment;

FIG. 6 is a table where parameters used in a test example C1 and comparative examples c1 and c2, respectively, obtained etching characteristics and SEM pictures are illustrated for the dry etching in accordance with a third experiment;

FIG. 7 is a vertical cross sectional view showing the structure of a microwave plasma etching apparatus for executing a dry etching method in accordance with the present invention;

FIG. 8 is a table where parameters used in test examples D1 to D4 and a comparative example d1, respectively, obtained etching characteristics and SEM pictures are illustrated for the dry etching in accordance with a fourth experiment; and

FIG. 9 is a table where parameters used in test examples E1 to E3 and a comparative example e1, respectively, obtained etching characteristics and SEM pictures are illustrated for the dry etching in accordance with a fifth experiment.

### DETAILED DESCRIPTION OF THE EMBODIMENTS

Some experiments in accordance with an embodiment of the present invention will now be described with reference to the accompanying drawings which form a part hereof.

### First Embodiment

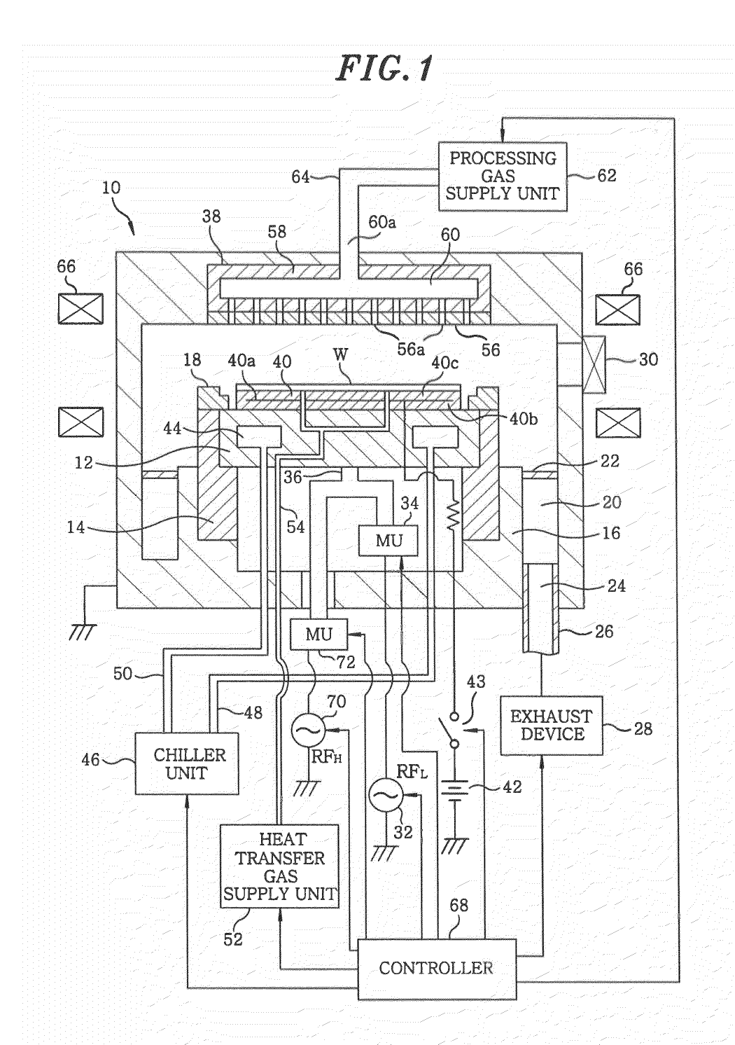

FIG. 1 shows the structure of a plasma etching apparatus for executing a dry etching method of the present invention. The plasma etching apparatus is of a capacitively coupled parallel plate type where dual RF frequencies are applied to a lower electrode, and includes a cylindrical chamber (processing chamber) 10 made of a metal, e.g., aluminum, stainless steel or the like. The chamber 10 is frame-grounded.

In the chamber 10, a cylindrical susceptor 12 serving as a lower electrode is placed to mount a target object (target substrate) thereon. The susceptor 12, which is made of, e.g., aluminum, is supported by an insulating tubular support 14, which is in turn supported by a cylindrical support 16 vertically extending from a bottom portion of the chamber 10 upwardly. A focus ring 18 made of, e.g., quartz or silicon is arranged on an upper surface of the tubular support 14 to annularly surround a peripheral part of a top surface of the susceptor 12.

An exhaust path 20 is formed between a sidewall of the chamber 10 and the cylindrical support 16. An annular baffle plate 22 is attached to the entrance or the inside of the exhaust path 20, and an exhaust port 24 is disposed at a bottom portion of the chamber 10. An exhaust device 28 is connected to the exhaust port 24 via an exhaust pipe 26. The exhaust device 28 includes a vacuum pump to evacuate an inner space of the chamber 10 to a predetermined vacuum level. Attached to the sidewall of the chamber 10 is a gate valve 30 for opening and closing a gateway through which a silicon wafer W is loaded or unloaded.

A first high frequency power supply 32 for attracting ions is electrically connected to the susceptor 12 via a first matching unit (MU) 34 and a power feed rod 36. The first high frequency power supply 32 supplies a first radio frequency power RF_{L} to the susceptor 12. The first radio frequency power RF_{L} has a frequency that is equal to or smaller than about 13.56 MHz, adequate to attract ions in the plasma to the silicon wafer W.

A second high frequency power supply 70 for generating a plasma is also electrically connected to the susceptor 12 via a second matching unit (MU) 72 and the power feed rod 36. The second high frequency power supply 70 supplies a second radio frequency power RF_{H} to the susceptor 12. The second radio frequency power RF_{H} has a frequency that is equal to or greater than about 40 MHz, adequate to discharge an etching gas by the radio frequency power.

At a ceiling portion of the chamber 10, a shower head 38 is placed as an upper electrode of ground potential. The first and the second radio frequency power RF_{L} and RF_{H} respectively supplied from the first and second high frequency power supply 32 and 70 are capacitively applied between the susceptor 12 and the shower head 38.

An electrostatic chuck 40 is placed on the top surface of the susceptor 12 to hold the silicon wafer W by an electrostatic force. The electrostatic chuck 40 includes an electrode 40a made of a conductive film and a pair of insulation films 40b and 40c. The electrode 40a is interposed between the insulation films 40b and 40c. A DC power supply 42 is electrically connected to the electrode 40a via a switch 43. By a DC voltage supplied from the DC power supply 42, the silicon wafer W can be attracted to and held by the electrostatic chuck 40 by the Coulomb force.

A coolant chamber 44, which extends in, e.g., a circumferential direction, is installed inside the susceptor 12. A coolant, e.g., a cooling water, of a predetermined temperature is circularly supplied from a chiller unit 46 to the coolant chamber 44 via pipelines 48 and 50. It is possible to control a process temperature of the silicon wafer W held on the electrostatic chuck 40 by adjusting the temperature of the coolant. Moreover, a heat transfer gas, e.g., He gas, is supplied from a heat transfer gas supply unit 52 to a space between a top surface of the electrostatic chuck 40 and a bottom surface of the silicon wafer W through a gas supply line 54.

The shower head 38 placed at the ceiling portion of the chamber 10 includes a lower electrode plate 56 having a plurality of gas injection holes 56a and an electrode support 58 that detachably supports the electrode plate 56. A buffer chamber 60 is provided inside the electrode support 58. A processing gas supply unit 62 is connected to a gas inlet opening 60a of the buffer chamber 60 via a gas supply line 64.

Provided along a circumference of the chamber 10 is a magnet unit 66 extending annularly or concentrically around the chamber 10. In the chamber 10, a high density plasma is generated near the surface of the susceptor 12 by the collective action of an RF electric field, which is produced between the shower head 38 and the susceptor 12 by the second radio frequency power RF_{H}, and a magnetic field generated by the magnet unit 66. In this embodiment, even though a plasma generation space inside the chamber 10, especially the plasma generation space between the shower head 38 and the susceptor 12 has a low pressure of about 1 mTorr (about 0.133 Pa), it is possible to obtain a high density plasma having electron density of about 1×10¹⁰/cm³ or more in order to execute the dry etching method of the present invention.

A controller 68 controls operations of various parts of the plasma etching apparatus, e.g., the exhaust device 28, the first high frequency power supply 32, the first matching unit 34, the switch 43, the chiller unit 46, the heat transfer gas supply unit 52, the processing gas supply unit 62, the second high frequency power supply 70, the second matching unit 72, and the like. The controller 68 is connected to a host computer (not shown) and the like.

In the present embodiment, a gaseous mixture mainly including a Cl₂ gas as an etching gas for silicon etching is supplied at a predetermined mixing ratio and a predetermined flow rate from the processing gas supply unit 62 to the chamber 10.

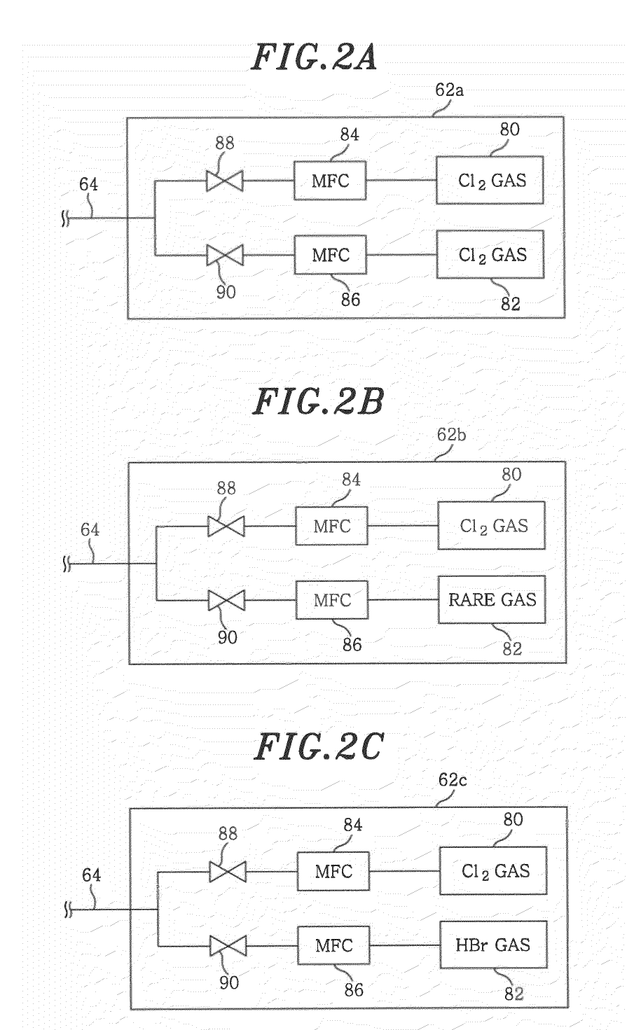

As an example of the processing gas supply unit 62, a processing gas supply unit 62a may include a cl₂ gas source 80, an O₂ gas source 82, mass flow controllers (MFC) 84 and 86, and opening valves 88 and 90 as shown in FIG. 2A. A gaseous mixture including a cl₂ and an O₂ gas is employed as the etching gas.

For another example, a processing gas supply unit 62b, as shown in FIG. 2B, may include the cl₂ gas source 80, a rare gas (e.g., an Ar or a He gas) source 92, the mass flow controllers (MFC) 84 and 86, and the opening valves 88 and 90. A gaseous mixture including the cl₂ and a rare gas is employed as the etching gas.

For still another example, a processing gas supply unit 62c, as shown in FIG. 2C, may include the cl₂ gas source 80, a HBr gas source 94, the mass flow controllers (MFC) 84 and 86, and the opening valves 88 and 90. A gaseous mixture including the cl₂ and a HBr gas is employed as the etching gas.

In the plasma etching apparatus, the gate valve 30 is opened first, and a target object, i.e., the silicon wafer W, is loaded in the chamber 10 and mounted on the electrostatic chuck 40 to perform the dry etching. Then, the etching gas is supplied from the processing gas supply unit 62 to the chamber 10 at a predetermined flow rate and mixing (flow rate) ratio, and the pressure inside the chamber 10 is adjusted by the exhaust device 28 at a preset level. Moreover, the first radio frequency power RF_{L} having a preset level is supplied from the first high frequency power supply 32 to the susceptor 12 and the second radio frequency power RF_{H} having a preset level is supplied from the second radio frequency power supply 70 to the susceptor 12.

A DC voltage is supplied from the DC power supply 42 to the electrode 40a of the electrostatic chuck 40 so that the silicon wafer W is firmly mounted on the electrostatic chuck 40. The etching gas injected from the shower head 38 is glow-discharged between the electrodes 12 and 38 to thereby be converted into a plasma. Radicals or ions generated in the plasma pass through openings in an etching mask on the surface of the silicon wafer W and react with the target object (e.g., the silicon substrate), thereby etching the target object in a desired pattern.

In such a dry etching process, the radio frequency power RF_{H} having a relatively high frequency (e.g., about 40 MHz or more, and preferably about 80 MHz to 300 MHz) supplied from the second radio frequency power supply 70 to the susceptor (lower electrode) 12 mainly contributes to the discharge of the etching gas or the generation of the plasma; and the first radio frequency power RF_{L} having a relatively low frequency (e.g., about 27 MHz or less, or preferably about 2 MHz to 13.56 MHz) supplied from the first high frequency power supply 32 to the susceptor (lower electrode) 12 mainly contributes to ion attraction from the plasma to the silicon wafer W.

During the dry etching, that is, while the plasma is generated in the processing space, a lower ion sheath is formed between the bulk plasma and the susceptor (lower electrode) 12. As a result, a negative self-bias voltage V_{dc}, having the substantially same magnitude as a voltage drop of the lower ion sheath, is produced at the susceptor 12 and the silicon wafer W. An absolute value |V_{dc}| of the self-bias voltage is in proportion to a peak-to-peak value Vₚₚ of the voltage of the first radio frequency power RF_{L} supplied to the susceptor 12.

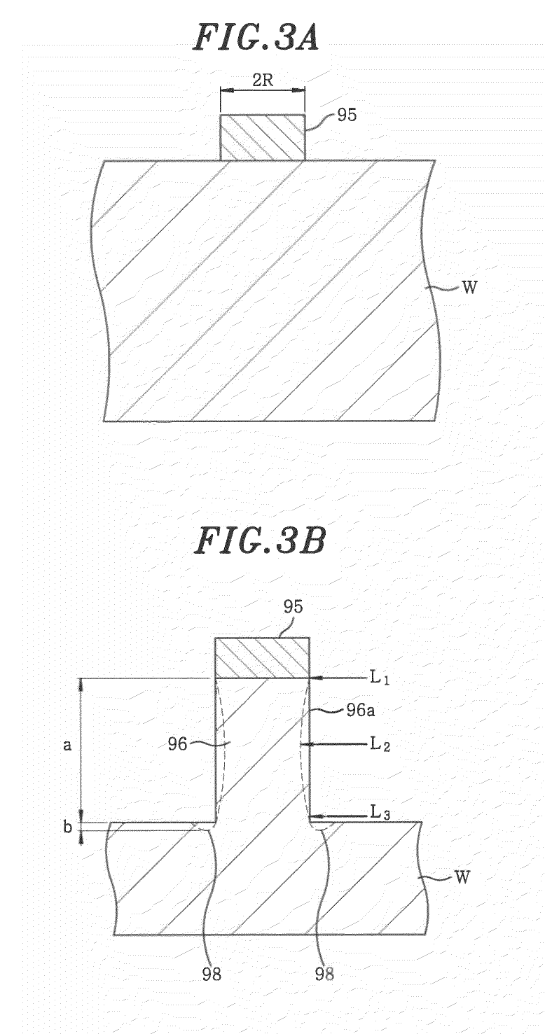

As an example of the etching process to which the present invention can be adequately applied, a dry etching method for forming a pillar-shaped element body for a vertical transistor on a main surface of the silicon wafer W in accordance to the embodiments of the present invention will be described below with reference to FIGS. 3A to 9.

As shown in FIG. 3A, in order to form such kind of pillar-shaped element body, a mask material (preferably, an inorganic film containing silicon) applied on a silicon wafer is patterned into a circular plate 95 having a diameter of 2R. Then, the silicon wafer W is etched down to a desired depth a by using the circular plate 95 as an etching mask. Accordingly, as shown in FIG. 3B, a cylindrical pillar-shaped element body 96 having desirable dimensions, e.g., the diameter 2R of about 200 nm and the depth a of about 200 nm, is formed on a main surface of the silicon wafer W.

Below are the important requirements for the silicon dry etching to form the pillar-shaped element body (or simply referred to as pillar) 96. First, damage to a sidewall 96a of the pillar 96 by ion impact or ion incidence thereon needs to be minimized or completely avoided. Second, the sidewall 96a of the pillar 96 needs to be etched to be as vertical as possible. (ideally, a taper angle θ is 90° ). Finally, the depth of a microtrench 98 which may be formed in a groove or a dent shape near the bottom edge of the pillar 96 needs to be minimized (ideally, the depth d is 0).

### (First Experiment)

In a first experiment, an etching experiment of forming the pillar-shaped element body 96 on the silicon wafer W was performed by executing the dry etching of the silicon wafer W under various conditions by using the capacitively coupled plasma etching apparatus shown in FIG. 1 and a gaseous mixture including a Cl₂ and an O₂ gas as an etching gas. The experiment was carried out by changing a mixing ratio of the Cl₂ and the O₂ gas as a main parameter. Main conditions are as follows.

Diameter of silicon wafer: 300 mm

Etching mask: SiN (150 nm)

Etching gas: Cl₂ gas/O₂ gas

Flow rates: Cl₂ gas=100 sccm, O₂ gas=0, 5, and 10 sccm

Pressure: 3 mTorr

First radio frequency power: 13 MHz, and bias RF power of 300 W

Second radio frequency power: 100 MHz, and RF power of 500 W

Distance between upper and lower electrodes: 30 mm

Temperature: upper electrode/sidewall of chamber/lower electrode=80/70/85° C.

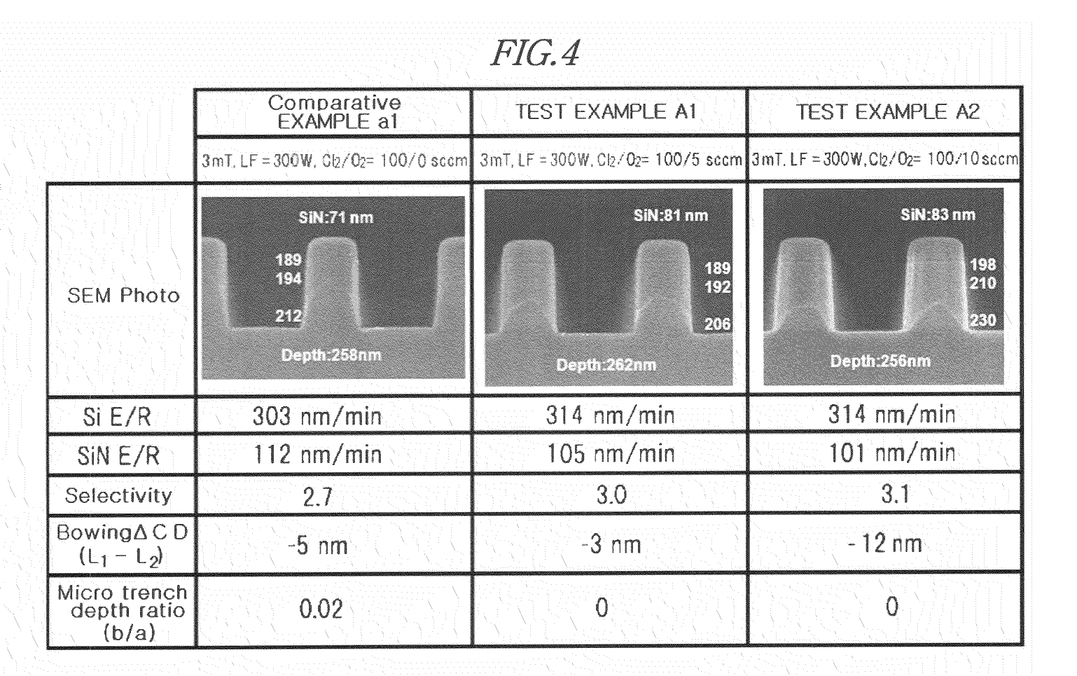

FIG. 4 is a table where parameters used in test examples A1 and A2 and a comparative example a1, respectively, obtained etching characteristics and SEM pictures are illustrated. All data in the test examples A1 and A2 and the comparative example a1 is obtained from a pattern sparse portion.

### Test Example A1

The gas pressure was 3 mTorr; the bias RF power was 300 W; and the flow rates of Cl₂ gas and O₂ gas were 100 sccm and 5 sccm, respectively, (mixing ratio is 0.05). The mask selectivity of 3.0, the bowing ΔCD of −3 nm and the microtrench depth ratio b/a of 0 were obtained.

In the SEM pictures shown in FIG. 4, in the case of, e.g., the test example A1, the following results were obtained. A diameter L₁ at the top of the pillar was 189 nm, a diameter L₂ at the middle of the pillar was 192 nm, a diameter L₃ at the bottom of the pillar was 206 nm, a height a of the pillar was 262 nm, and the depth b of the microtrench was 0 nm.

### Test Example A2

The gas pressure was 3 mTorr; the bias RF power was 300 W; and the flow rates of Cl₂ gas and O₂ gas were 100 sccm and 10 sccm, respectively, (mixing ratio is 0.10). The mask selectivity of 3.1, the bowing ΔCD of −12 nm and the microtrench depth ratio b/a of 0 were obtained.

### Comparative Example a1

The gas pressure was 3 mTorr; the bias RF power was 300 W; and the flow rates of Cl₂ gas and O₂ gas were 100 sccm and 0 sccm, respectively, (mixing ratio is 0). The mask selectivity of 2.7, the bowing ΔCD of −5 nm and the micro depth ratio b/a of 0.02 were obtained.

As shown in FIG. 3B, the bowing ΔCD is a factor for evaluating the vertical shape of the etched sidewall of the pillar 96 and is the difference (L₁−L₂) obtained by subtracting the diameter L₂ at the middle of the pillar 96 from the diameter L₁ at the top of the pillar 96. If the bowing ΔCD is a positive value, the pillar 96 has a bowing shape. In contrast, if the bowing ΔCD is a negative value, the pillar 96 has a taper shape. As an absolute value of the bowing ΔCD gets smaller, the sidewall of the pillar 96 is more vertically etched. Moreover, the microtrench depth ratio is a factor for evaluating the formation of microtrench and is the ratio (b/a) obtained by dividing the depth b of the microtrench by the height a of the pillar 96. The smaller the microtrench depth ratio gets, the less the microtrench is formed.

As a result, as compared with in the comparative example a1 in which the single gas of Cl₂ was employed, the mask selectivity was enhanced from 2.7 to 3.0; the absolute value of the bowing ΔCD was decreased from |−5| nm to |−3| nm; and the microtrench depth ratio is decreased from 0.02 to 0, in the test example A1 in which the mixing ratio of the O₂ gas to the Cl₂ gas was 0.05 (5%). However, if the mixing ratio of the O₂ gas to the Cl₂ gas and is increased from 0 to 10 (10%) in the test example A2, the mask selectivity is slightly enhanced from 3.0 to 3.1 but the absolute value of the bowing ΔCD was increased from |−5| nm to |−12| nm. The microtrench depth ratio was not changed.

As a result, when employing the gaseous mixture including the cl₂ gas and the O₂ gas as the etching gas as in the test examples A1 and A2, it is preferable that the mixing ratio of the O₂ gas to the cl₂ gas is 0.05 (5%) to 0.10 (10%).

Moreover, in the case of adding the O₂ gas to the cl₂ gas, the temperature of the susceptor (lower electrode) 12 may be increased to control or prevent deposition of a reaction product (SiO₂). For example, it is preferable to set the temperature of the susceptor 12 as 85° C. or higher as in this experiment.

### (Second Experiment)

In a second experiment, an etching experiment of forming the pillar-shaped element body 96 on the silicon wafer W was performed by executing the dry etching of the silicon wafer W under various conditions by using the capacitively coupled plasma etching apparatus shown in FIG. 1 and a gaseous mixture including the Cl₂ and a rare gas as an etching gas. The experiment was carried out by changing a mixing ratio of the Cl₂ and the rare gas as a main parameter. Main conditions are as follows.

Diameter of silicon wafer: 300 mm

Etching mask: SiN (150 nm)

Etching gas: Cl₂ gas/rare gas (Ar gas and He gas)

Flow rates: Cl₂ gas=100 sccm, Ar gas=400 and 900 sccm, and He gas=400 sccm

Pressure: 20 mTorr

First radio frequency power: 13 MHz, and bias RF power of 400 W

Second radio frequency power: 100 MHz, and RF power of 600 W

Distance between upper and lower electrodes: 30 mm

Temperature: upper electrode/sidewall of chamber/lower electrode=80/60/30° C.

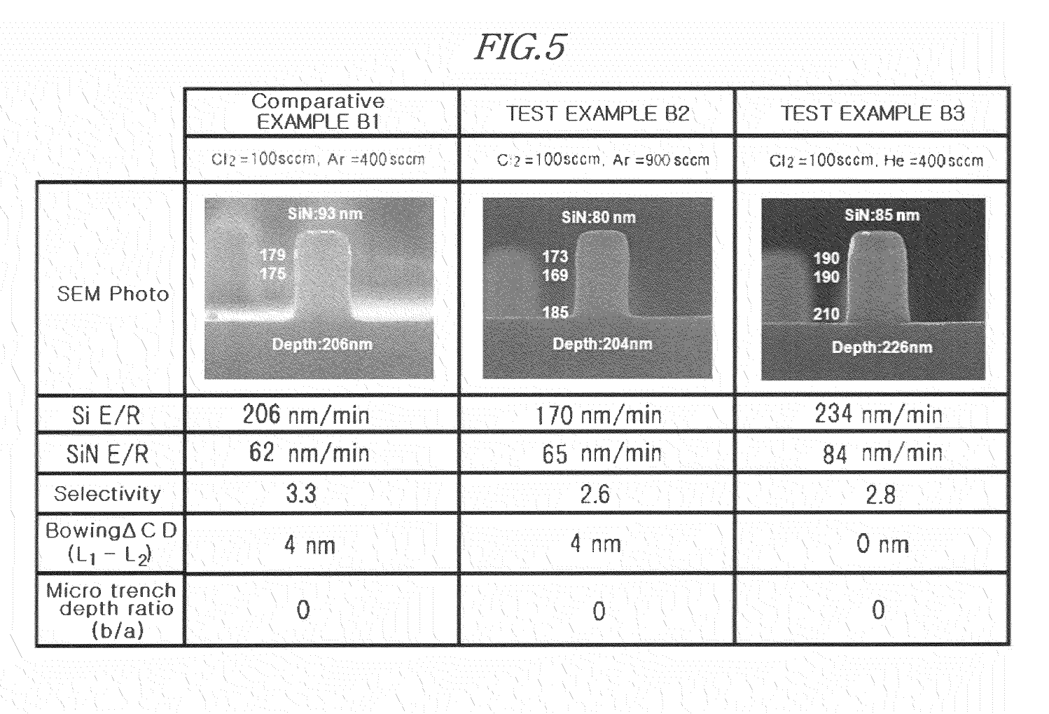

FIG. 5 is a table where parameters used in test examples B1 to B3, respectively, obtained etching characteristics and SEM pictures are illustrated for the dry etching in accordance with a second experiment of the embodiment. All data in the test examples B1 to B3 is obtained from a pattern sparse portion.

### Test Example B1

The flow rates of Cl₂ gas and Ar gas were 100 sccm and 400 sccm, respectively, (mixing ratio is 4). The mask selectivity of 3.3, the bowing ΔCD of 4 nm and the microtrench depth ratio b/a of 0 were obtained.

In the SEM pictures shown in FIG. 5, in the case of, e.g., the test example B1, the following results were obtained. A diameter L₁ at the top of the pillar was 179 nm, a diameter L₂ at the middle of the pillar was 175 nm, a diameter L₃ at the bottom of the pillar was 206 nm, a height a of the pillar was 206 nm, and the depth b of the microtrench was 0 nm.

### Test Example B2

The flow rates of Cl₂ gas and Ar gas were 100 sccm and 900 sccm, respectively, (mixing ratio is 9). The mask selectivity of 2.6, the bowing ΔCD of 4 nm and the microtrench depth ratio b/a of 0 were obtained.

### Test Example B3

The flow rates of Cl₂ gas and He gas were 100 sccm and 400 sccm, respectively, (mixing ratio is 4). The mask selectivity of 2.8, the bowing ΔCD of 0 nm and the microtrench depth ratio b/a of 0 were obtained.

Accordingly, it can be seen from the second experiment that the adequate mask selectivity and the bowing removing effect can be obtained and the pillar can have its bottom edge portion having a round shape (accordingly, it is difficult that the microtrench is formed) by employing a gaseous mixture in which the rare gas (Ar or He gas) is added to the Cl₂ gas in the mixing ratio of 4 to 9 as in the test experiments B1 to B3.

### (Third Experiment)

In a third experiment, an etching experiment of forming the pillar-shaped element body 96 on the silicon wafer W was performed by executing the dry etching of the silicon wafer W under various conditions by using the capacitively coupled plasma etching apparatus shown in FIG. 1 and a gaseous mixture including the Cl₂ and a HBr gas as an etching gas. The experiment was carried out by changing a mixing ratio of the Cl₂ and the HBr gas as a main parameter. Main conditions are as follows.

Diameter of silicon wafer: 300 mm

Etching mask: SiN (150 nm)

Etching gas: Cl₂ gas/HBr gas

Flow rates: Cl₂ gas=0, 50, and 100 sccm, HB r gas=0, 50, and 100 sccm

Pressure: 20 mTorr

First radio frequency power: 13 MHz, and bias RF power of 400 W

Second radio frequency power: 100 MHz, and RF power of 600 W

Distance between upper and lower electrodes: 30 mm

Temperature: upper electrode/sidewall of chamber/lower electrode=80/60/60° C.

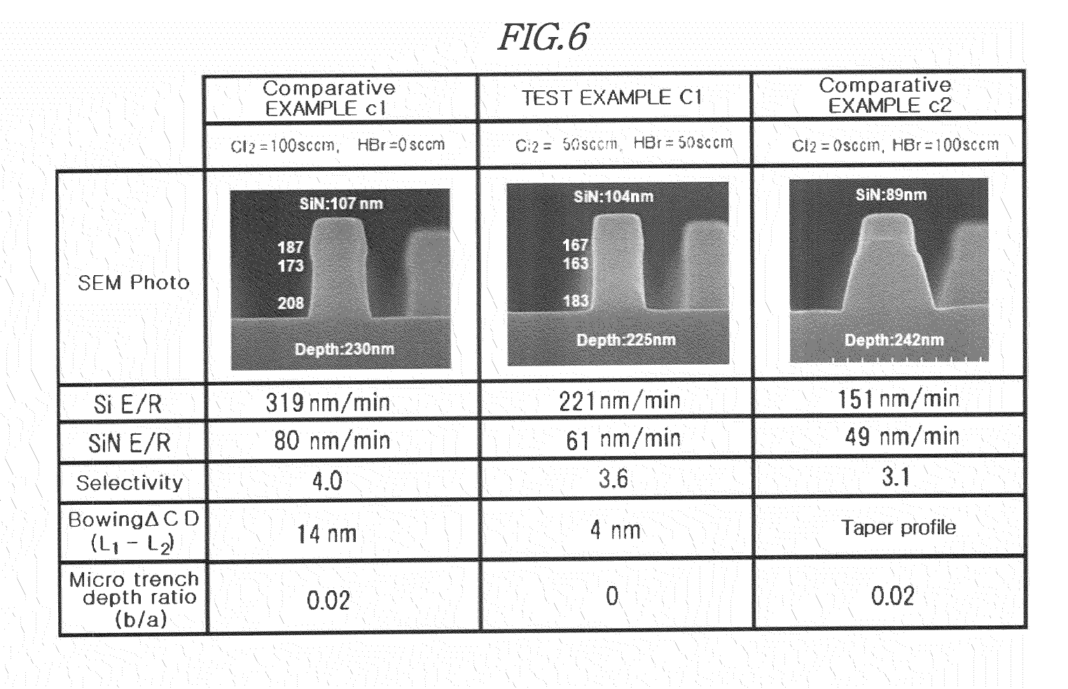

FIG. 6 is a table where parameters used in a test example C1 and comparative examples c1 and c2, respectively, obtained etching characteristics and SEM pictures are illustrated for the dry etching in accordance with a third experiment of the embodiment. All data in the test example C1 and the comparative examples c1 and c2 is obtained from a pattern sparse portion.

### Test Example C1

The flow rates of Cl₂ gas and HBr gas were 50 sccm and 50 sccm, respectively, (mixing ratio is 1). The mask selectivity of 3.6, the bowing ΔCD of 4 nm and the microtrench depth ratio b/a of 0 were obtained.

In the SEM pictures shown in FIG. 6, in the case of, e.g., the test example C1, the following results were obtained. A diameter L₁ at the top of the pillar was 167 nm, a diameter L₂ at the middle of the pillar was 163 nm, a diameter L₃ at the bottom of the pillar was 183 nm, a height a of the pillar was 225 nm, and the depth b of the microtrench was 0 nm.

### Comparative Example c1

The flow rates of Cl₂ gas and HBr gas were 100 sccm and sccm, respectively, (mixing ratio is 0). The mask selectivity of 4.0, the bowing ΔCD of 14 nm and the microtrench depth ratio b/a of 0.02 were obtained.

### Comparative example c2

The flow rates of Cl₂ gas and HBr gas were 0 sccm and 100 sccm, respectively. The mask selectivity of 3.1, significant taper shape and the microtrench depth ratio b/a of 0.02 were obtained.

As a result, as compared with in the comparative example c1 in which the single gas of Cl₂ was employed, the mask selectivity was slightly decreased from 4.0 to 3.6; but the absolute value of the bowing ΔCD was decreased from 1141 nm to 141 nm; and the microtrench depth ratio is decreased from 0.02 to 0, in the test example A1 in which the mixing ratio of the HBr gas to the Cl₂ gas was 1 (50%). However, if the mixing ratio of the HBr gas to the Cl₂ gas is too greater, the pillar has the taper shape and it is difficult to prevent the microtrench from being formed.

Accordingly, it is preferable that the mixing ratio of the HBr gas to the Cl₂ gas is 1 as in the test example C1.

### Second Embodiment

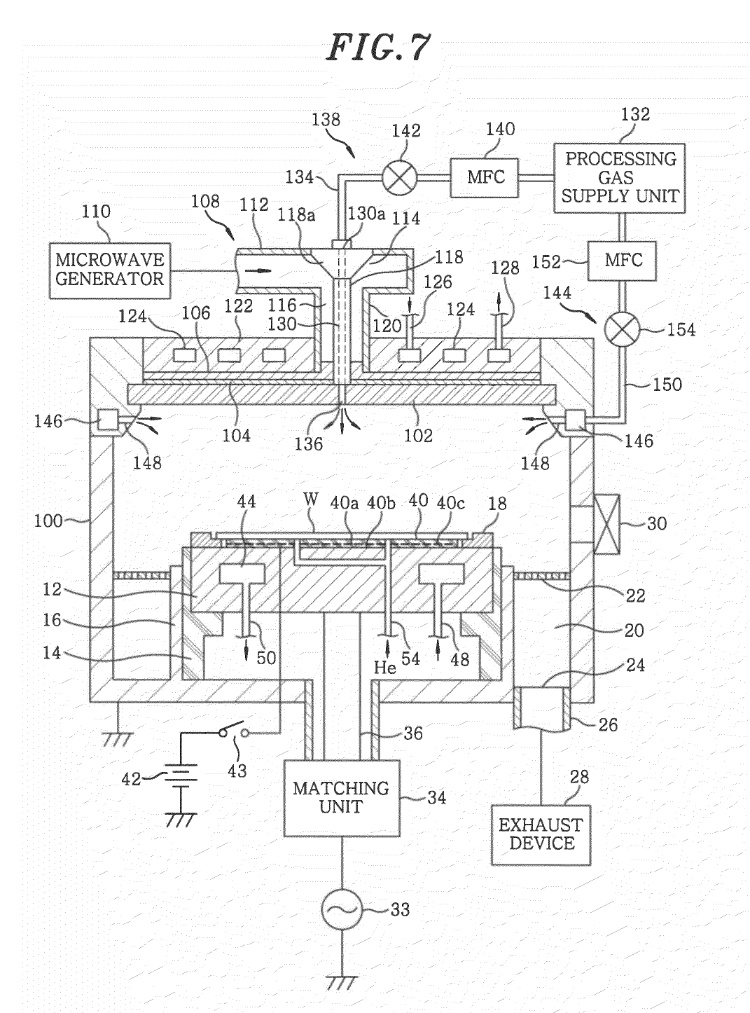

FIG. 7 shows the structure of another plasma etching apparatus for executing a dry etching method of the present invention. This plasma etching apparatus is a plate-type surface-wave plasma (SWP) etching apparatus where a plasma is generated by using a microwave (referred to as a microwave plasma etching apparatus hereinafter), and includes a cylindrical chamber (processing chamber) 100 made of a metal, e.g., aluminum, stainless steel or the like. The chamber 100 is frame-grounded.

Since, in the microwave plasma etching apparatus, parts not involving in the plasma generation have substantially the same configurations and functions as those of the aforementioned capacitively coupled plasma etching apparatus, such parts are denoted by like reference characters, and thus redundant description thereof will be omitted herein.

Hereinafter, the structure of parts involving in the plasma generation of the microwave plasma etching apparatus will be described.

Airtightly attached to a ceiling portion of the chamber 100 facing the susceptor 12 is a circular quartz plate 102, i.e., a dielectric plate for introducing a microwave. As a plate-type slot antenna, a circular plate shaped radial line slot antenna 104 having a plurality of slots is installed on an upper surface of the quartz plate 102. The slots are concentrically arranged in the radial line slot antenna 104. The radical line slot antenna 104 is electromagnetically connected to a microwave transmission line 108 via a retardation plate 106 made of a dielectric material, e.g., quartz or the like.

A microwave outputted from a microwave generator 110 is transmitted to the antenna 104 through the microwave transmission line 108. The microwave transmission line 108 includes a waveguide 112, a mode converting portion 114, and a coaxial tube 116. Through the waveguide 112, e.g., a rectangular waveguide, a microwave generated from the microwave generator is transmitted to the mode converting portion 114 in a direction toward the chamber 100 by a transverse electric (TE) mode as its transmission mode.

In the mode converting portion 114, the rectangular waveguide 112 and the coaxial tube 116 are joined to each other to convert the transmission mode of the rectangular waveguide 112 to a transmission mode of the coaxial tube 116. In the case of transmitting a great microwave power, it is preferable that an upper portion 118a of an inner conductor 118 has an inverse taper shape (so-called a doorknob shape), the thickness of which gets thicker from its top portion to its bottom portion as shown in FIG. 7 to prevent the concentration of electric field.

The coaxial tube 116 vertically downwardly extends from the mode converting portion 114 to a center portion of an upper surface of the chamber 100 such that an end portion or a lower portion of the coaxial tube 116 is connected to the antenna 104 via the retardation plate 106. An outer conductor 120 of the coaxial tube 116 has a cylindrical body and the outer conductor 120 and the rectangular waveguide 112 are formed as a single unit. The microwave is propagated through a space between the inner conductor 118 and the outer conductor 120 by a transverse electromagnetic (TEM) mode.

The microwave outputted from the microwave generator 110 is propagated through the aforementioned microwave transmission line 108 including the waveguide 112, the mode converting portion 114, and the coaxial tube 116. Then, the propagated microwave is transmitted to the antenna 104 via the retardation plate 106. Specifically, the microwave propagated in a radical direction in the retardation plate 106 is radiated through the slots of the antenna 104 toward the chamber 100. Accordingly, gases around the quartz plate 102 are ionized to generate a plasma by the power of the microwave radiated from a surface wave propagating along the surface of the quartz plate 102.

An antenna back plate 122 is installed on the retardation plate 106 to cover the upper surface of the chamber 100. The antenna back plate 122 made of, e.g., aluminum serves as a cooling jacket that absorbs (transmits) heat generated from the quartz plate 102. The antenna back plate 122 includes flow paths 124 formed therein. A coolant, e.g., a cooling water, of a predetermined temperature is circularly supplied from a chiller unit (not shown) to the flow paths 124 via pipelines 126 and 128.

In this embodiment, as shown in FIG. 7, a hollow gas flow path 130 is installed to extend through in the inner conductor 118 of the coaxial tube 116. A top opening 130a of the gas flow path 130 is connected to a processing gas supply source 132 via a first gas supply line 134. An upper central gas discharge openings 136 is formed at a central portion of the quartz plate 102 while communicating with a lower opening of the gas flow path 130.

A first processing gas inlet 138 has the following structure. The processing gas supplied from the processing gas supply source 132 is transferred via the first gas supply line 134 and the gas flow path 130 of coaxial tube 116 to the upper central gas discharge opening 136 and then downwardly discharged toward the susceptor 12 disposed directly thereunder. The discharged processing gas is radially outwardly diffused by being attracted to the annularly shaped exhaust path 20 surrounding the susceptor 12. A mass flow controller (MFC) 140 and an opening valve 142 are installed on the first gas supply line 134.

In the present embodiment, a second processing gas inlet 144 is further provided to introduce the processing gas to the chamber 100 by using a different way from that of the first processing gas inlet 138. The second processing gas inlet 144 includes a buffer chamber 146, a plurality of lateral gas discharge openings 148, and a second gas supply line 150. The buffer chamber 146 is annularly formed in a sidewall of the chamber 100 and slightly located lower than the quartz plate 102. The lateral gas discharge openings 148 are arranged at regular intervals in a circumstantial direction while facing from the buffer chamber 146 toward a plasma generation space. The second gas supply line 150 extends from the processing gas supply source 132 to the buffer chamber 146. Moreover, a mass flow controller (MFC) 152 and an opening valve 154 are installed inside the first gas supply line 134.

Etching gases introduced from the processing gas supply source 132 to the chamber 100 via the first processing gas inlet 138 and the second processing gas inlet 144 are gaseous mixtures mainly including Cl₂ gases. In detailed, the processing gas supply source 132 includes, e.g., a Cl₂ gas source, a CF₄ gas source, a SF₆ gas source, and an O₂ gas source, which are not shown. In a fourth experiment, a gaseous mixture including a Cl₂ gas, a CF₄ gas, and an O₂ gas are employed. In a fifth experiment, a gaseous mixture including a Cl₂ gas, a SF₆ gas, and an O₂ gas are employed.

In the microwave plasma etching apparatus, the gate valve 30 is opened first, and a target object, i.e., the silicon wafer W, is loaded in the chamber 100 and mounted on the electrostatic chuck 40 to perform the dry etching. Then, the etching gas (gaseous mixture) is supplied from the processing gas inlets 138 and 144 to the chamber 100 at a predetermined flow rate and mixing (flow rate) ratio, and the pressure inside the chamber 100 is adjusted by the exhaust device 28 at a preset level. Moreover, a first radio frequency power RF_{L} having a preset level is outputted by turning on a high frequency power supply 33 and supplied to the susceptor 12 via the matching unit 34 and the power feed rod 36. The switch 43 is turned on to supply a DC voltage from the DC power supply 42 to the electrode 40a of the electrostatic chuck 40 so that the silicon wafer W is firmly mounted on the electrostatic chuck 40.

Then, the microwave generator 110 is turned on to generate a microwave and the generated microwave is supplied to the antenna 104 via the microwave transmission line 108. The microwave is radiated from the antenna 104 and then introduced to the chamber 100 via the quartz plate 102.

The etching gases are introduced from the upper central gas discharge openings 136 of the first processing gas inlet 138 and the lateral gas discharge openings 148 of the second processing gas inlet 144 to the chamber 100 and are diffused below the quartz plate 102. Then, the gas particles are ionized by the microwave power radiated surface waves propagated along a lower surface (surface facing the plasma) of the quartz plate 102 to generate surface excitation plasmas. As such, the plasmas generated below the quartz plate 102 are downwardly diffused and the isotropic etching by radicals in the plasmas and the vertical etching by ion radiation are performed on the silicon wafer W.

### (Fourth Experiment)

In a fourth experiment, an etching experiment of forming the pillar-shaped element body 96 on the silicon wafer W was performed by executing the dry etching of the silicon wafer W under various conditions by using the microwave plasma etching apparatus shown in FIG. 7 and a gaseous mixture including a Cl₂, a CF₄ (carbon tetra fluoride) and an O₂ gas as the etching gas. The experiment was carried out by changing a mixing ratio of the Cl₂, the CF₄, and the O₂ gas as a main parameter. Main conditions are as follows.

Diameter of silicon wafer: 300 mm

Etching mask: SiN (150 nm)

Etching gas: Cl₂ gas/CF₄ gas/O₂ gas

Flow rates: Cl₂ gas=500 sccm, CF₄ gas=0, 100, 200 sccm, O₂ gas=0, 20, and 30 sccm

Pressure: 20 mTorr

Microwave power=2000 W

Bias RF power=900 W

Temperature: quartz plate/sidewall of chamber/electrode=80/80/40° C.

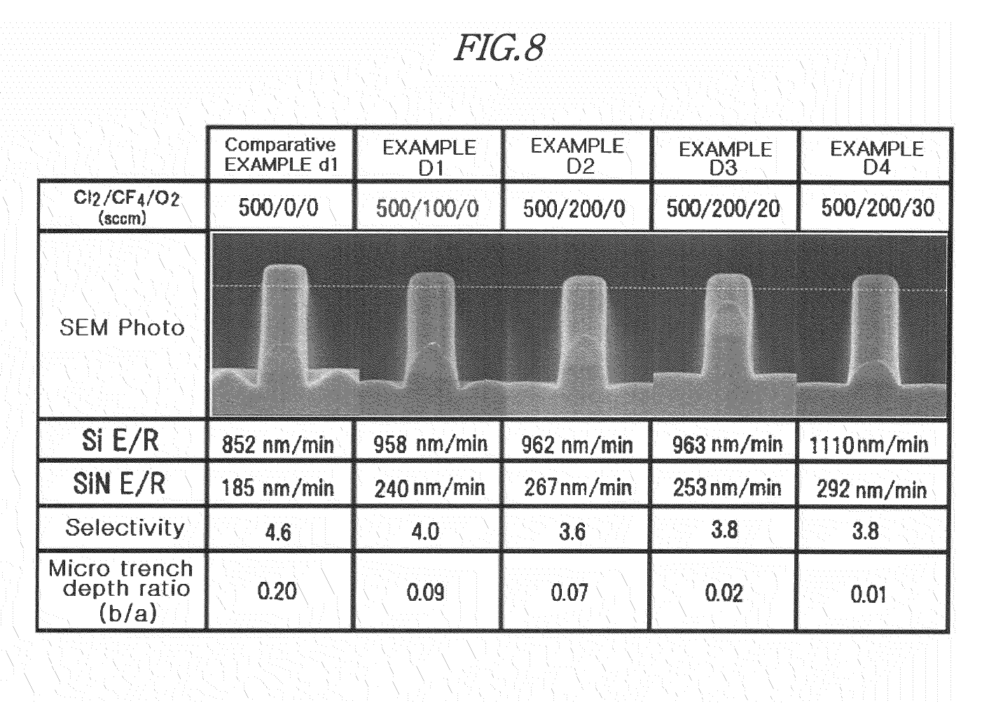

FIG. 8 is a table where parameters used in test examples D1 to D4 and a comparative example d1, respectively, obtained etching characteristics and SEM pictures are illustrated. All data in the test examples D1 to D4 and the comparative example d¹ is obtained from a pattern sparse portion.

### Test Example D1

The flow rates of the Cl₂, the CF₄, and the O₂ gas were 500 sccm, 100 sccm and 0 sccm, respectively, (mixing ratio of CF₄ is 0.2). The mask selectivity of 4.0 and the microtrench depth ratio b/a of 0.09 were obtained.

### Test Example D2

The flow rates of the Cl₂, the CF₄, and the O₂ gas were 500 sccm, 200 sccm and 0 sccm, respectively, (mixing ratio of CF₄ is 0.4). The mask selectivity of 3.6 and the microtrench depth ratio b/a of 0.07 were obtained.

### Test Example D3

The flow rates of the Cl₂, the CF₄, and the O₂ gas were 500 sccm, 200 sccm and 20 sccm, respectively, (mixing ratios of CF₄ and O₂ are 0.4 and 0.04, respectively). The mask selectivity of 3.8 and the microtrench depth ratio b/a of 0.02 were obtained.

### Test Example D4

The flow rates of the Cl₂, the CF₄, and the O₂ gas were 500 sccm, 200 sccm and 30 sccm, respectively, (mixing ratios of CF₄ and O₂ are 0.4 and 0.06, respectively). The mask selectivity of 3.8 and the microtrench depth ratio b/a of 0.01 were obtained.

### Comparative Example d1

The flow rates of the Cl₂, the CF₄, and the O₂ gas were 500 sccm, 0 sccm and 0 sccm, respectively, (i.e., single gas of Cl₂). The mask selectivity of 4.6 and the microtrench depth ratio b/a of 0.20 were obtained.

As a result, it is possible to largely reduce (prevent) the formation of microtrench by adequately adding the CF₄ gas to the Cl₂ gas. Moreover, as the mixing ratio of the CF₄ gas is increased, it is likely to decrease the selectivity. However, if the O₂ gas as well as the CF₄ gas is added to the Cl₂ gas, the selectivity is enhanced, thereby reducing (preventing) the formation of microtrench much more.

The reason that the formation of microtrench is significantly prevented by adding the CF₄ gas (F based gas) is that an etching inhibitor (reaction product including Si and Cl) deposited on a bottom portion of an etched surface (a bottom portion between the pillars 96) is removed by fluorine ion radiation. Not a few fluorine ions are incident on the silicon wafer W inclinedly as well as accurately vertically. Most of the fluorine ions that are incident inclinedly are more easily accumulated on a central region of the bottom portion than on an end region of the bottom portion (bottom edge portion of the pillar 96). Accordingly, the etching inhibitor is efficiently removed in the central region of the bottom portion by the fluorine ions, thereby performing the etching at a high etching rate.

In the fourth experiment, the bowing ΔCD was not measured. However, it can be visually seen from the SEM pictures shown in FIG. 8 that the vertical processability is sufficiently high in the test examples D1 to D4, especially, the highest vertical processability is shown in the test examples D3 and D4.

### (Fifth Experiment)

In a fifth experiment, an etching experiment of forming the pillar-shaped element body 96 on the silicon wafer W was performed by executing the dry etching of the silicon wafer W under various conditions by using the microwave plasma etching apparatus shown in FIG. 7 and a gaseous mixture including a Cl₂, a SF₆ (sulfur hexafluoride) and an O₂ gas as an etching gas. The experiment was carried out by changing a mixing ratio of the Cl₂, the SF₆, and the O₂ gas as a main parameter. Main conditions are as follows.

Diameter of silicon wafer: 300 mm

Etching mask: SiN (150 nm)

Etching gas: Cl₂ gas/SF₆ gas/O₂ gas

Flow rates: Cl₂ gas=500 sccm, SF₆ gas=0, 30, 100 sccm, O₂ gas ═0 and 30 sccm

Pressure: 20 mTorr

Microwave power=2000 W

Bias RF power=900 W

Temperature: quartz plate/sidewall of chamber/electrode=80/80/80° C.

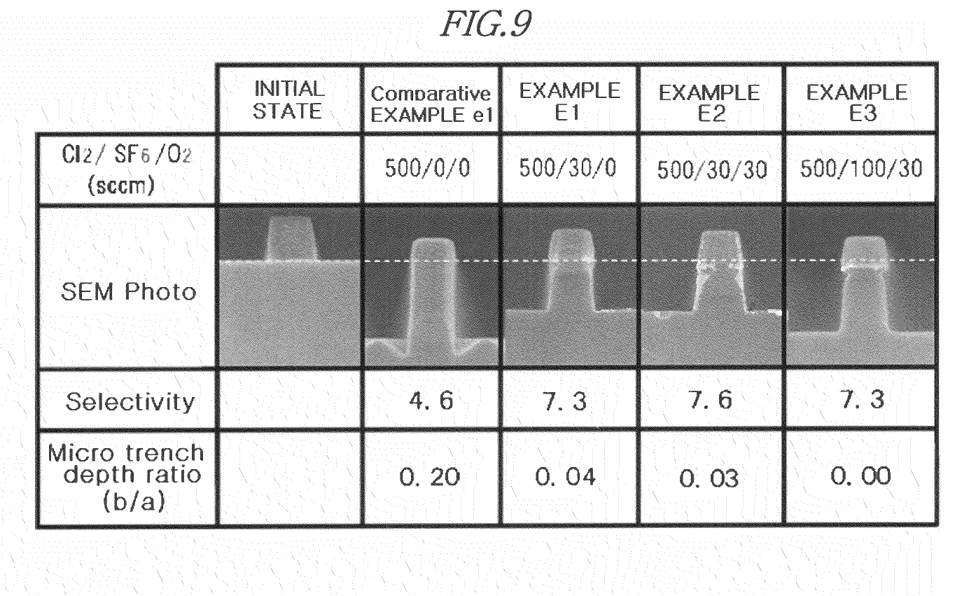

FIG. 9 is a table where parameters used in test examples E1 to E3 and a comparative example e1, respectively, obtained etching characteristics and SEM pictures are illustrated. All data in the test examples E1 to E3 and the comparative example e1 is obtained from a pattern sparse portion.

### Test Example E1

The flow rates of the Cl₂, the SF₆, and the O₂ gas were 500 sccm, 30 sccm and 0 sccm, respectively, (mixing ratio of SF₆ is 0.6). The mask selectivity of 7.3 and the microtrench depth ratio b/a of 0.04 were obtained.

### Test Example E2

The flow rates of the Cl₂, the SF₆, and the O₂ gas were 500 sccm, 30 sccm and 30 sccm, respectively, (mixing ratios of SF₆ and O₂ are 0.06 and 0.06, respectively). The mask selectivity of 7.6 and the microtrench depth ratio b/a of 0.03 were obtained.

### Test Example E3

The flow rates of the Cl₂, the SF₆, and the O₂ gas were 500 sccm, 100 sccm and 30 sccm, respectively, (mixing ratios of SF₆ and O₂ are 0.2 and 0.06, respectively). The mask selectivity of 7.3 and the microtrench depth ratio b/a of 0.00 were obtained.

Comparative example e1

The flow rates of the Cl₂, the SF₆, and the O₂ gas were 500 sccm, 0 sccm and 0 sccm, respectively, (i.e., single gas of Cl₂). The mask selectivity of 4.6 and the microtrench depth ratio b/a of 0.20 were obtained.

As a result, it is possible to largely enhance the selectivity and reduce (prevent) the formation of microtrench by adequately adding the SF₆ gas to the Cl₂ gas. Moreover, the formation of microtrench can be reduced much more by adding the O₂ gas as well as the SF₆ gas to the Cl₂ gas.

It can be visually seen from the SEM pictures shown in FIG. 9 that the vertical processability is sufficiently maintained even though it is likely that the etched pillar 96 has a taper shape by the SF₆ gas addition.

From the fourth and fifth experiments, it is inferred that a fluorine based gas excluding the CF₄ and SF₆ gas, e.g., NF₃, can be also employed as the etching gas to perform the etching in accordance with the embodiments of the present invention by changing various conditions. Moreover, a N₂ gas can be used at a different mixing ratio instead of the O₂ gas.

The present invention is adequately applicable to a dry etching for forming a pillar-shaped element body for a vertical transistor as in the aforementioned embodiments. However, the present invention is also applicable to a typical Si trench etching and further to an etching of a silicon layer for forming a gate electrode of plate-type metal insulator semiconductor field effect transistor (MISFET).

In the capacitively coupled plasma etching apparatus (FIG. 1) in accordance with the first embodiment of the present invention, the high frequency power RF_{H} for generating a plasma may be applied to the upper electrode. In accordance with the first and the second embodiment of the present invention, the dry etchings in the first to third experiment are carried out by employing the capacitively coupled plasma etching apparatus (FIG. 1) and the dry etchings in the fourth and fifth experiment are carried out by employing the microwave plasma etching apparatus (FIG. 7). However, the dry etchings in the first to third experiment can be carried out by employing the microwave plasma etching apparatus (FIG. 7) and the dry etchings in the fourth and fifth experiment can be carried out by employing the capacitively coupled plasma etching apparatus (FIG. 1). Further, the dry etching of the present invention can be carried out by employing anther type plasma etching apparatus, e.g., an inductively coupled plasma etching apparatus.

In accordance with the dry etching method of the present invention, it is possible to prevent the formation of microtrench and enhance the vertical processability and the mask selectivity in an etching process of a silicon substrate, especially in an etching process for forming a three-dimensional structure on a silicon substrate with the above configurations and functions.

While the invention has been shown and described with respect to the embodiments, it will be understood by those skilled in the art that various changes and modification may be made without departing from the scope of the invention as defined in the following claims.

What is claimed is:

1. A dry etching method comprising:
mounting a silicon substrate in a processing chamber;
generating a plasma by discharging an etching gas in the processing chamber; and
etching the silicon substrate by the plasma,
wherein the etching gas is a gaseous mixture including a Cl₂ gas and one of an O₂ gas, a rare gas, a HBr gas, a CF₄ gas, and a SF₆ gas.

2. The method of claim 1, wherein the etching gas is a gaseous mixture including the Cl₂ gas and the O₂ gas.

3. The method of claim 2, wherein a mixing ratio of the Cl₂ gas to the O₂ gas is about 0.05 to 0.1.

4. The method of claim 1, wherein the etching gas is a gaseous mixture including the Cl₂ gas and the rare gas.

5. The method of claim 4, wherein a mixing ratio of the Cl₂ gas to the rare gas is about 4 to 9.

6. The method of claim 1, wherein the etching gas is a gaseous mixture including the Cl₂ gas and the HBr gas.

7. The method of claim 6, wherein a mixing ratio of the Cl₂ gas to the HBr gas is about 1.

8. The method of claim 1, wherein the etching gas is a gaseous mixture including the Cl₂ gas and the CF₄ gas.

9. The method of claim 8, wherein a mixing ratio of the Cl₂ gas to the CF₄ gas is about 0.4 to 0.5.

10. The method of claim 8, wherein the gaseous mixture further includes an O₂ gas.

11. The method of claim 1, wherein the etching gas is a gaseous mixture including the Cl₂ gas and the SF₆ gas.

12. The method of claim 11, wherein a mixing ratio of the Cl₂ gas to the SF₆ gas is about 0.01 to 0.2.

13. The method of claim 11, wherein the gaseous mixture further includes an O₂ gas.

14. The method of claim 1, wherein the silicon substrate is mounted in an electrode arranged in the processing chamber, and
a radio frequency power for attracting ions from the plasma is supplied to the electrode.

15. The method of claim 14, wherein an additional electrode is disposed in the processing chamber in parallel with the electrode with a gap therebetween and an additional radio frequency power for discharging the etching gas is supplied to the electrode or the additional electrode.

16. The method of claim 14, wherein the etching gas is excited to generate the plasma by a power of a microwave radiated from an antenna into the processing chamber via a dielectric material placed facing the electrode by supplying the microwave to the antenna, the antenna being arranged outside the dielectric material.

17. The method of claim 1, wherein a three-dimensional element body having a cylindrical or a rectangular parallelepiped shape is formed on a main surface of the silicon substrate by etching the silicon substrate.

18. The method of claim 1, wherein the etching is carried out by using an inorganic film containing silicon as an etching mask.

19. The method of claim 18, wherein the etching mask includes silicon nitride.
